(19) United States
(12) Patent Application Publication
(10) Pub. No.: US 2010/0124816 A1
(43) Pub. Date: May 20, 2010

(54) Reticles and methods of forming semiconductor devices

(75) Inventor: Sanghoon Park, Hwaseong-si (KR)

Correspondence Address: HARNESS, DICKEY & PIERCE, P.L.C., P.O. BOX 8910, RESTON, VA, 20195, US

(73) Assignee: Samsung Electronics Co., Ltd.

(21) Appl. No.: 12/588,718

(22) Filed: Oct. 26, 2009

(30) Foreign Application Priority Data
Nov. 18, 2008 (KR) 10-2008-0114592

(51) Int. Cl. H01L 21/28

(52) U.S. Cl. 438/586; 257/E21.19

(57) ABSTRACT

A reticle may include a transparent substrate, a first phase pattern having a first thickness disposed on the transparent substrate, a chrome pattern disposed on the first phase pattern, and a second phase pattern having a second thickness disposed on the transparent substrate. The first phase pattern and the chrome pattern may be disposed to overlap with each other. A method of forming a semiconductor device may include forming a gate insulating layer and a gate electrode on a semiconductor substrate, forming a spacer on a sidewall of the gate electrode, forming an interlayer insulating layer over an exposed surface of the semiconductor substrate, and forming a common contact hole. The contact hole may include a first portion exposing the gate electrode, a second portion exposing the semiconductor substrate, and a third portion connecting the first and second portions, by patterning the interlayer insulating layer.

### CROSS-REFERENCE TO RELATED APPLICATION(S)

This application claims priority from Korean Patent Application No. 10-2008-0114592, filed on Nov. 18, 2008, in the Korean Intellectual Property Office (KIPO), the entire contents of which are incorporated herein by reference.

### BACKGROUND

1. Field

Example embodiments relate to reticles and methods of forming semiconductor devices. Also, example embodiments relate to reticles and methods of forming semiconductor devices using a phase shift mask.

2. Description of the Related Art

A static random access memory (SRAM) may have an advantage of low power consumption and/or a high operational speed when compared with a dynamic random access memory (DRAM). A static random access memory (SRAM) may have a common contact plug.

### SUMMARY

Exemplary embodiments provide reticles. The reticles may include a transparent substrate, a first phase pattern having a first thickness disposed on the transparent substrate, a chrome pattern disposed on the first phase pattern, and/or a second phase pattern having a second thickness disposed on the transparent substrate. The first phase pattern and the chrome pattern may be disposed to overlap with each other.

The first thickness may be thicker than the second thickness.

The first phase pattern may surround the second phase pattern.

The first phase pattern may protrude in comparison with the chrome pattern.

The first phase pattern and/or the second phase pattern may include one or both molybdenum (Mo) and silicon (Si).

The first thickness may be greater than or equal to about 80 nanometers (nm) and less than or equal to about 100 nm.

The second thickness may be greater than or equal to about 10 nm and less than or equal to about 100 nm.

Transmittance of the first phase pattern and/or the second phase pattern may be greater than or equal to about 10 percent and less than or equal to about 25 percent.

Exemplary embodiments provide methods of forming semiconductor devices. The methods may include forming a gate insulating layer and a gate electrode on a semiconductor substrate, forming a spacer on a sidewall of the gate electrode, forming an interlayer insulating layer over an entire surface of the semiconductor substrate, and/or forming a common contact hole including a first portion exposing the gate electrode, a second portion exposing the semiconductor substrate, and a third portion connecting the first and second portions by patterning the interlayer insulating layer. In the methods, the common contact hole may be formed by etching the interlayer insulating layer using a common contact mask pattern as an etch mask. The common contact mask pattern may be formed by using a reticle. The reticle may include a transparent substrate, a first phase pattern of a first thickness disposed on the transparent substrate, a chrome pattern disposed on the first phase pattern, and/or a second phase pattern of a second thickness disposed on the transparent substrate. The third portion may be formed to correspond to the second phase pattern. The first phase pattern and the chrome pattern may be disposed to overlap each other. The first thickness may be thicker than the second thickness.

The third portion may be disposed to overlap with the spacer, and the interlayer insulating layer may remain on the third portion.

According to example embodiments, a reticle may include a transparent substrate, a first phase pattern having a first thickness disposed on the transparent substrate, a chrome pattern disposed on the first phase pattern, and/or a second phase pattern having a second thickness disposed on the transparent substrate. The first phase pattern and the chrome pattern may be disposed to overlap with each other.

According to example embodiments, a method of forming a semiconductor device may include forming a gate insulating layer and a gate electrode on a semiconductor substrate, forming a spacer on a sidewall of the gate electrode, forming an interlayer insulating layer over an exposed surface of the semiconductor substrate, and/or forming a common contact hole. The common contact hole may include a first portion exposing the gate electrode, a second portion exposing the semiconductor substrate, and/or a third portion connecting the first and second portions, by patterning the interlayer insulating layer. The common contact hole may be formed by etching the interlayer insulating layer using a common contact mask pattern as an etch mask. The common contact mask pattern may be formed by using a reticle. The reticle may include a transparent substrate, a first phase pattern of a first thickness disposed on the transparent substrate, a chrome pattern disposed on the first phase pattern, and/or a second phase pattern of a second thickness disposed on the transparent substrate. The third portion may be formed to correspond to the second phase pattern. The first phase pattern and the chrome pattern may be disposed to overlap each other. The first thickness may be thicker than the second thickness.

### BRIEF DESCRIPTION OF THE DRAWINGS

The above and/or other aspects and advantages will become more apparent and more readily appreciated from the following detailed description of example embodiments taken in conjunction with the accompanying drawings, in which:

FIGS. 1A through 1C are top plan views and cross-section views illustrating reticles in accordance with example embodiments;

FIGS. 2A through 2C are top plan views and cross-section views illustrating reticles in accordance with example embodiments;

FIGS. 3A through 3D are cross-section views illustrating methods of forming reticles in accordance with example embodiments;

FIG. 4 is an equivalent circuit view of a general complimentary metal-oxide-semiconductor (CMOS) SRAM;

FIGS. 5A through 5C are top plan views and cross-section views illustrating a semiconductor device in accordance with example embodiments;

FIGS. 6A and 6B are cross-section views taken along the lines V-V′ and VI-VI′ of FIG. 5A to illustrate methods of forming semiconductor devices in accordance with example embodiments; and

FIGS. 7A and 7B are cross-section views taken along the lines V-V′ and VI-VI′ of FIG. 5A to illustrate methods of forming a semiconductor devices in accordance with example embodiments.

### DETAILED DESCRIPTION

Example embodiments will now be described more fully with reference to the accompanying drawings. Embodiments, however, may be embodied in many different forms and should not be construed as being limited to the embodiments set forth herein. Rather, these example embodiments are provided so that this disclosure will be thorough and complete, and will fully convey the scope to those skilled in the art. In the drawings, the thicknesses of layers and regions are exaggerated for clarity.

It will be understood that when an element is referred to as being “on,” “connected to,” “electrically connected to,” or “coupled to” to another component, it may be directly on, connected to, electrically connected to, or coupled to the other component or intervening components may be present. In contrast, when a component is referred to as being “directly on,” “directly connected to,” “directly electrically connected to,” or “directly coupled to” another component, there are no intervening components present. As used herein, the term “and/or” includes any and all combinations of one or more of the associated listed items.

It will be understood that although the terms first, second, third, etc., may be used herein to describe various elements, components, regions, layers, and/or sections, these elements, components, regions, layers, and/or sections should not be limited by these terms. These terms are only used to distinguish one element, component, region, layer, and/or section from another element, component, region, layer, and/or section. For example, a first element, component, region, layer, and/or section could be termed a second element, component, region, layer, and/or section without departing from the teachings of example embodiments.

Spatially relative terms, such as “beneath,” “below,” “lower,” “above,” “upper,” and the like may be used herein for ease of description to describe the relationship of one component and/or feature to another component and/or feature, or other component(s) and/or feature(s), as illustrated in the drawings. It will be understood that the spatially relative terms are intended to encompass different orientations of the device in use or operation in addition to the orientation depicted in the figures.

The terminology used herein is for the purpose of describing particular example embodiments only and is not intended to be limiting. As used herein, the singular forms “a,” “an,” and “the” are intended to include the plural forms as well, unless the context clearly indicates otherwise. It will be further understood that the terms “comprises,” “comprising,” “includes,” and/or “including,” when used in this specification, specify the presence of stated features, integers, steps, operations, elements, and/or components, but do not preclude the presence or addition of one or more other features, integers, steps, operations, elements, and/or components.

Example embodiments may be described with reference to cross-sectional illustrations, which may be schematic illustrations of idealized example embodiments. As such, variations from the shapes of the illustrations, as a result, for example, of manufacturing techniques and/or tolerances, may be expected. Thus, example embodiments should not be construed as limited to the particular shapes of regions illustrated herein, but are to include deviations in shapes that result from, e.g., manufacturing. For example, a region illustrated as a rectangle may have rounded or curved features. Thus, the regions illustrated in the figures are schematic in nature and are not intended to limit the scope of example embodiments.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning that is consistent with their meaning in the context of the relevant art and should not be interpreted in an idealized or overly formal sense unless expressly so defined herein.

Reference will now be made to example embodiments, which are illustrated in the accompanying drawings, wherein like reference numerals may refer to like components throughout.

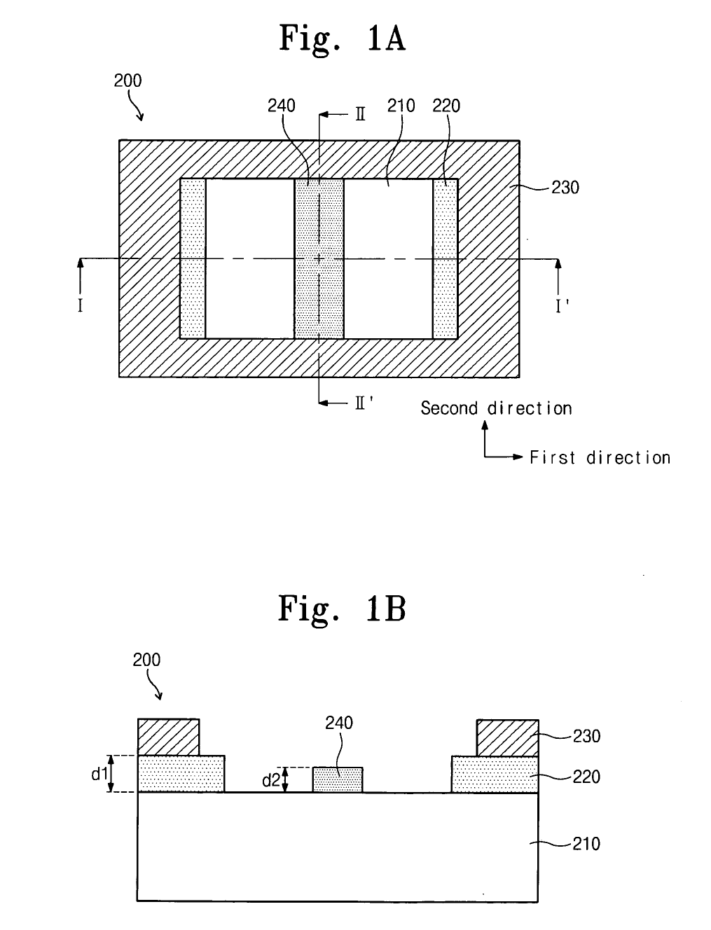

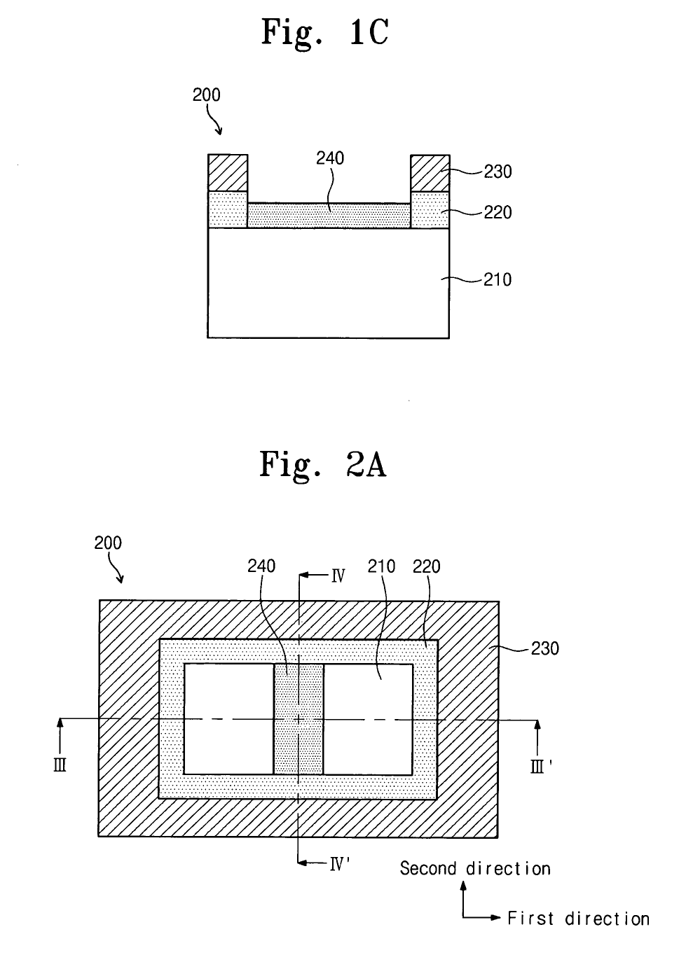

FIGS. 1A through 1C are top plan views and cross-section views illustrating reticles in accordance with example embodiments. FIG. 1B is a cross-section view taken along the line I-I′ of FIG. 1A. FIG. 1C is a cross-section view taken along the line II-II′ of FIG. 1A.

Referring to FIGS. 1A through 1C, a reticle 200 may include a transparent substrate 210, a first phase pattern 220 having a first thickness (d1) disposed on the transparent substrate 210, a chrome pattern 230 disposed on the first phase pattern 220, and/or a second phase pattern 240 having a second thickness (d2) disposed on the transparent substrate 210. The first phase pattern 220 and the chrome pattern 230 may be disposed to overlap with each other and/or the first thickness (d1) may be greater than the second thickness (d2).

The transparent substrate 210 may be quartz. The first phase pattern 220 and/or the second phase pattern 240 may include one or more of Molybdenum (Mo), Silicon (Si), Oxygen (O), and Nitrogen (N). The first phase pattern 220 may surround the second phase pattern 240. The first phase pattern 220 may protrude in a first direction compared with the chrome pattern 230. The first phase pattern 220 may be in contact with the second phase pattern 240, for example, at a second direction crossing the first direction. Transmittances of the first phase pattern 220 and/or the second phase pattern 240 may be greater than or equal to about 10 percent and less than or equal to about 25 percent. The first thickness (d1) of the first phase pattern 220 may be greater than or equal to about 80 nm and less than or equal to about 100 nm. The second thickness (d2) of the second phase pattern 240 may be greater than or equal to about 10 nm and less than or equal to about 100 nm. The chrome pattern 230 may not be disposed on the second phase pattern 240. An amount of a remaining photoresist (not shown) during an exposure process may be changed depending on transmittance of the second phase pattern 240.

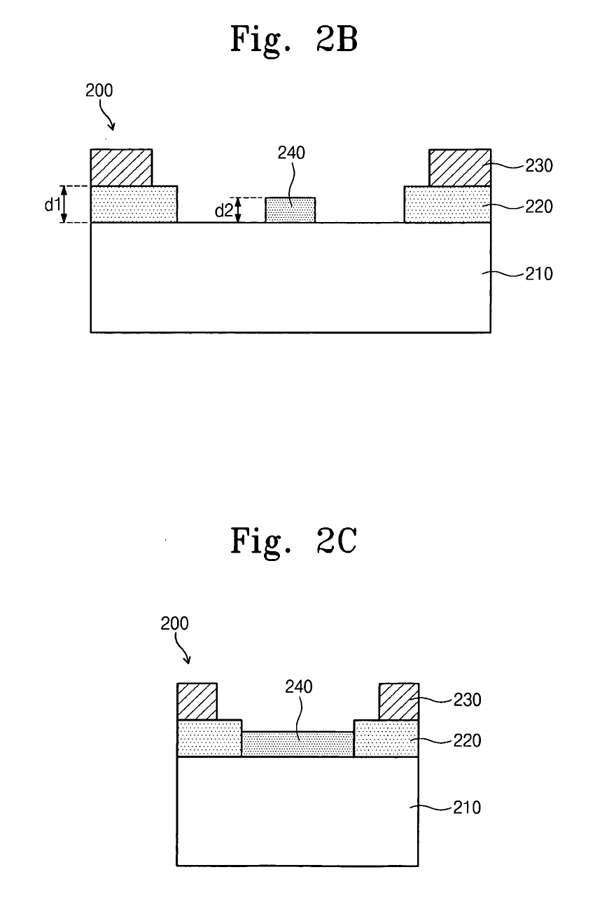

FIGS. 2A through 2C are top plan views and cross-section views illustrating reticles in accordance with example embodiments. FIG. 2B is a cross-section view taken along the line III-III′ of FIG. 2A. FIG. 2C is a cross-section view taken along the line IV-IV′ of FIG. 2A.

Referring to FIGS. 2A through 2C, a reticle 200 may include a transparent substrate 210, a first phase pattern 220 having a first thickness (d1) disposed on the transparent substrate 210, a chrome pattern 230 disposed on the first phase pattern 220, and/or a second phase pattern 240 having a second thickness (d2) disposed on the transparent substrate 210. The first phase pattern 220 and the chrome pattern 230 may be disposed to overlap with each other and/or the first thickness (d1) may be greater than the second thickness (d2).

The transparent substrate 210 may be quartz. The first phase pattern 220 and/or the second phase pattern 240 may include one or more of Molybdenum (Mo), Silicon (Si), Oxygen (O), and Nitrogen (N). The first phase pattern 220 may surround the second phase pattern 240. The first phase pattern 220 may protrude in a first direction and/or in a second direction crossing the first direction compared with the chrome pattern 230. The first phase pattern 220 may be in contact with the second phase pattern 240, for example, at a second direction crossing the first direction. Transmittances of the first phase pattern 220 and/or the second phase pattern 240 may be greater than or equal to about 10 percent and less than or equal to about 25 percent. The first thickness (d1) of the first phase pattern 220 may be greater than or equal to about 80 nm and less than or equal to about 100 nm. The second thickness (d2) of the second phase pattern 240 may be greater than or equal to about 10 nm and less than or equal to about 100 nm. The chrome pattern 230 may not be disposed on the second phase pattern 240. An amount of a remaining photoresist (not shown) during an exposure process may be changed depending on transmittance of the second phase pattern 240.

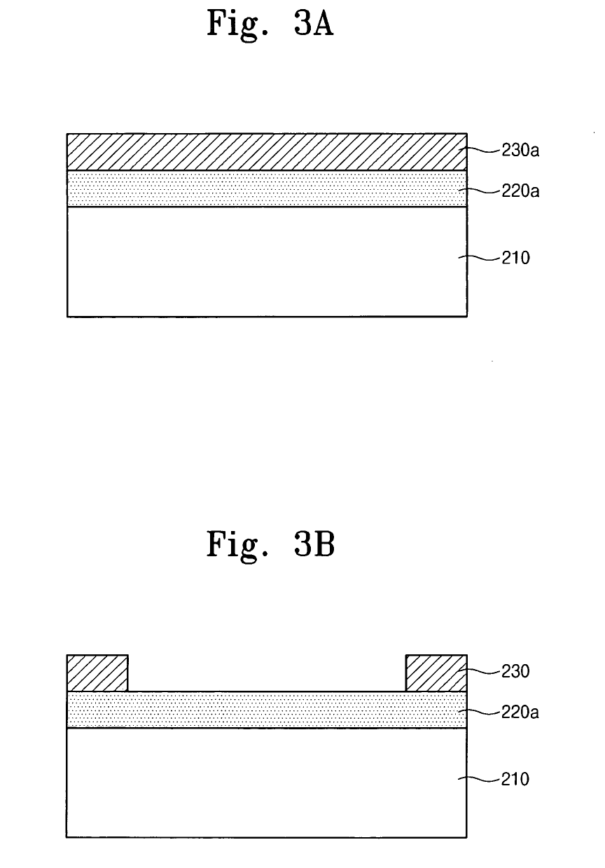

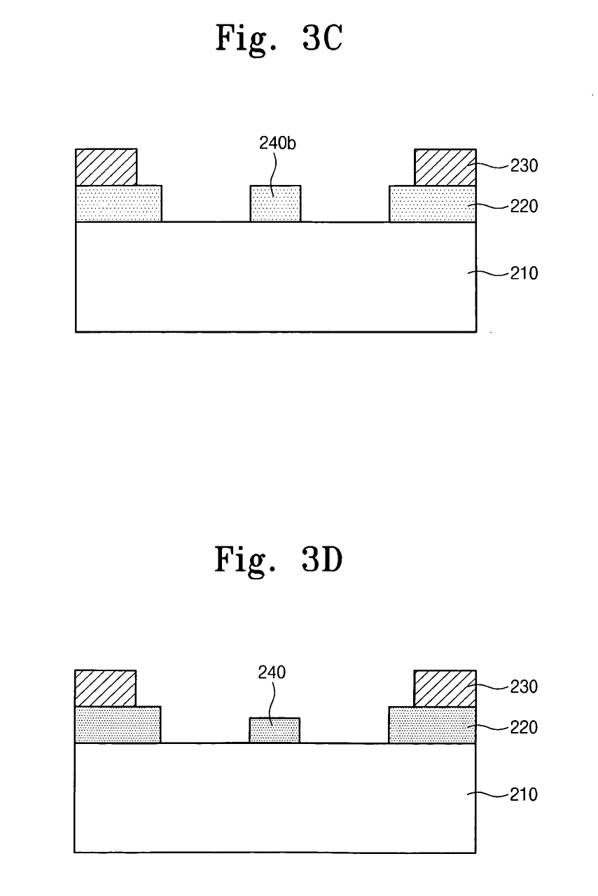

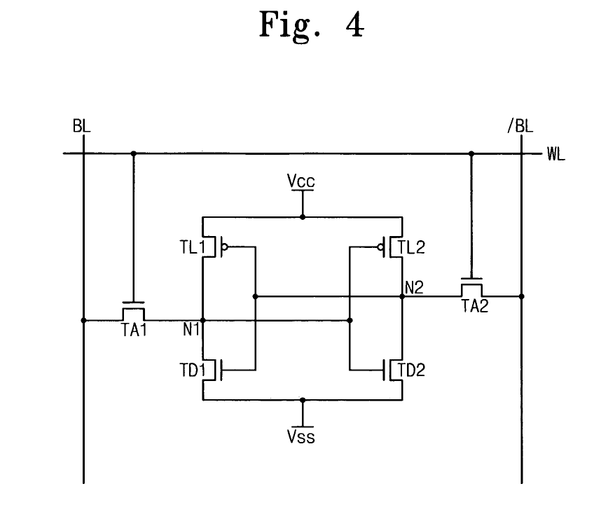

FIGS. 3A through 3D are cross-section views illustrating methods of forming reticles in accordance with example embodiments. FIGS. 3A through 3D are cross-section views taken along the line I-I′ of FIG. 1A.

Referring to FIG. 3A, a first phase layer 220a and a chrome layer 230a may be sequentially stacked on a transparent substrate 210. The transparent substrate 210 may be a quartz substrate. The first phase layer 220a may include one or both of Molybdenum (Mo) and Silicon (Si). The first phase layer 220a may be MoSiON. The chrome layer 230a may include chrome.

Referring to FIG. 3B, a first photoresist pattern (not shown) may be formed on the chrome layer 230a, and/or the chrome layer 230a may be selectively etched using the first photoresist pattern as an etching mask in order to form a chrome pattern 230. The first photoresist pattern may be formed using, for example, an electronic beam lithography technique.

Referring to FIG. 3C, a second photoresist pattern (not shown) may be formed on the transparent substrate 210 including the chrome pattern 230, and/or the first phase layer 220a may be selectively etched using the second photoresist pattern as an etching mask in order to form a first phase pattern 220 and/or a second preliminary phase pattern 240b.

Referring to FIG. 3D, a third photoresist pattern (not shown) may be formed on the transparent substrate 210 including the first phase pattern 220 and the second preliminary phase pattern 240b, and/or the second preliminary phase pattern 240b may be etched using the third photoresist pattern as an etching mask in order to form a second phase pattern 240. Thus, a thickness of the first phase pattern 220 may be, for example, greater than a thickness of the second phase pattern 240.

FIG. 4 is an equivalent circuit view of a general complimentary metal-oxide-semiconductor (CMOS) SRAM.

Referring to FIG. 4, a CMOS SRAM may include a pair of drive transistors (TD1, TD2), a pair of transmission transistors (TA1, TA2), and/or a pair of load transistors (TL1, TL2). In example embodiments, the pair of drive transistors (TD1, TD2) and/or the pair of transmission transistors (TA1, TA2) may be NMOS transistors, while the pair of load transistors (TL1, TL2) may be PMOS transistors.

The first drive transistor (TD1) and the first transmission transistor (TA1) may be serially connected to each other. A source region of the first drive transistor (TD1) may be connected to a ground line (Vss) and/or a drain region of the first transmission transistor (TA1) may be connected to a first bit line (BL). Similarly, the second drive transistor (TD2) and the second transmission transistor (TA2) may be serially connected to each other. A source region of the second drive transistor (TD2) may be connected to a ground line (Vss) and/or a drain region of the second transmission transistor (TA2) may be connected to a second bit line (/BL).

A source region of the first load transistor (TL1) may be connected to a power line (Vcc) and/or a drain region of the first load transistor (TL1) may be connected to a drain region of the first drive transistor (TD1). A source region of the second load transistor (TL2) may be connected to the power line (Vcc) and/or a drain region of the second load transistor (TL2) may be connected to a drain region of the second drive transistor (TD2). The drain region of the first load transistor (TL1), the drain region of the first drive transistor (TD1), and/or a source region of the first transmission transistor (TA1) may correspond to a first node (N1). Also, a drain region of the second load transistor (TL2), the drain region of the second drive transistor (TD2), and/or a source region of the second transmission transistor (TA2) may correspond to a second node (N2). A gate electrode of the first drive transistor (TD1) and/or a gate electrode of the first load transistor (TL1) may be connected to the second node (N2). A gate electrode of the second drive transistor (TD2) and/or a gate electrode of the second load transistor (TL2) may be connected to the first node (N1). The first transmission transistor (TA1) and/or the second transmission transistor (TA2) may be connected to a word line (WL).

The equivalent circuit view of the CMOS SRAM cell may be realized in a semiconductor substrate in various types. The gate electrode of the second drive transistor (TD2) and/or the gate electrode of the second load transistor (TL2) may be electrically connected to the drain region of the first load transistor (TL1), the drain region of the first drive transistor (TD1), and/or the source region of the first transmission transistor (TA1) at the first node (N1).

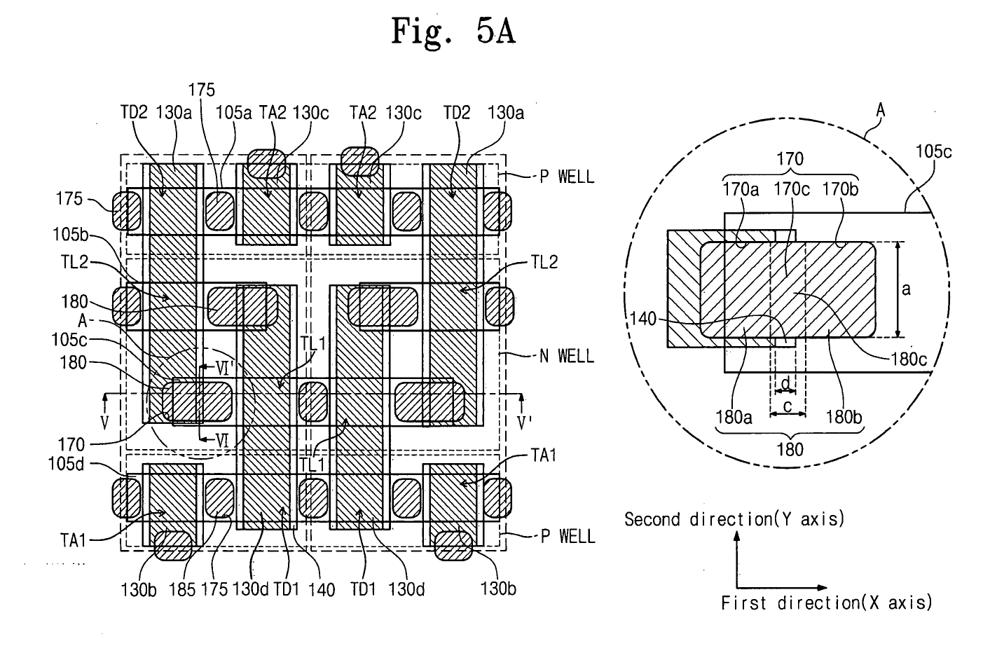

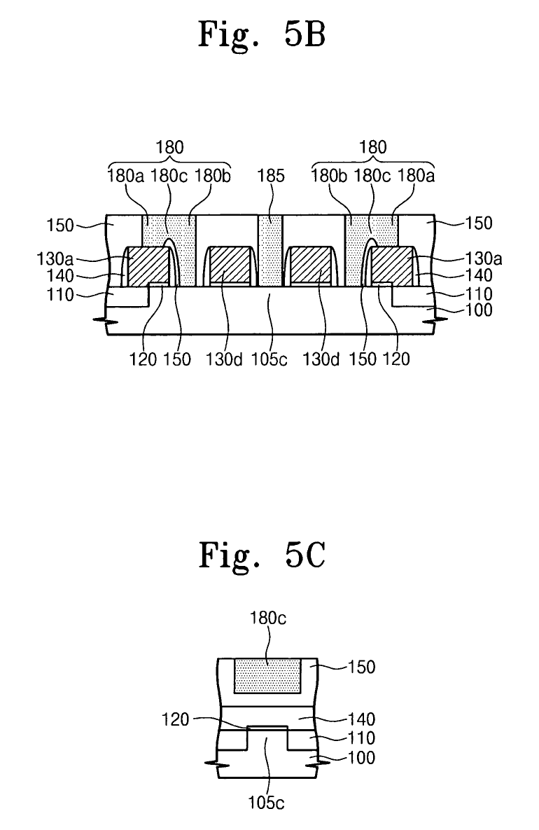

FIGS. 5A through 5C are top plan views and cross-section views illustrating a semiconductor device in accordance with example embodiments. FIG. 5B is a cross-section view taken along the line V-V′ of FIG. 5A. FIG. 5C is a cross-section view taken along the line VI-VI′ of FIG. 5A. Here, the top plan view shows two unit cells. Two unit cells adjacent to each other along an X axis (a first direction) may symmetrically extend with respect to a Y axis (a second direction). Two unit cells adjacent to each other along the Y axis may be symmetrically disposed with respect to the X axis (not shown).

Referring to FIGS. 4 and 5A through 5C, to realize a CMOS SRAM, the drain of the first drive transistor (TD1) and the source of the first transmission transistor (TA1) may be formed in the same active region to be shared. The gate electrode of the second drive transistor (TD2) and/or the gate electrode of the second load transistor (TL2) may be connected to a common gate electrode. The common gate electrode and the drain region of the first load transistor (TL1) may be connected to each other using a common contact plug. Since the drain region of the first load transistor (TL1) may exist in an active region of the semiconductor substrate, the common contact plug may have different heights according to a location of the common contact plug.

The common contact plug may be formed by forming a common contact hole and then filling the common contact hole with conductive material. When an etching process is performed to form the common contact hole, a spacer disposed on a sidewall of the common gate electrode may be etched over due to a height difference between the common gate electrode and the semiconductor substrate, resulting in damage to the spacer. The damage to the spacer may degrade an operational characteristic and/or reliability of the associated semiconductor device. Thus, it may be desired to prevent damage to the spacer.

Referring to FIGS. 5A through 5C, first, second, third, and/or fourth active regions 105a, 105b, 105c, and/or 105d spaced apart from each other in a Y axis direction may be disposed in the semiconductor substrate 100. The first, second, third, and/or fourth active regions 105a, 105b, 105c, and/or 105d may extend in parallel to an X axis. The first, second, third, and/or fourth active regions 105a, 105b, 105c, and/or 105d may be defined, at least in part, by a device isolation layer 110. Extended lengths of the first active region 105a and/or the fourth active region 105d may be greater than extended lengths of the second active region 105b and/or the third active region 105c. The second active region 105b may be aligned with a left of a unit cell region and/or the third active region 105c may be aligned with a right of a unit cell region.

A first gate electrode 130a may be disposed to cross an upper portion or portions of the first active region 105a and/or the second active region 105b, and/or to cover a portion of an edge of the third active region 105c. A second gate electrode 130b may be disposed to cross an upper portion of the fourth active region 105d. A third gate electrode 130c may be disposed to cross an upper portion of the first active region 105a. A fourth gate electrode 130d may be disposed to cross an upper portion or portions of the third active region 105c and/or the fourth active region 105d, and/or to cover a portion of an edge of the second active region 105b.

Transistors may be defined, at least in part, by the gate electrodes 130a-d and/or the active regions 105a-d. More specifically, the second drive transistor (TD2) may be defined by the first active region 105a and/or the first gate electrode 130a, the second load transistor (TL2) may be defined by the second active region 105b and/or the first gate electrode 130a, the first transmission transistor (TA1) may be defined by the fourth active region 105d and/or the second gate electrode 130b, the second transmission transistor (TA2) may be defined by the first active region 105a and/or the third gate electrode 130c, the first load transistor (TL1) may be defined by the third active region 105c and/or the fourth gate electrode 130d, and the first drive transistor (TD1) may be defined by the fourth active region 105d and/or the fourth gate electrode 130d. The first load transistor (TL1) and/or the second load transistor (TL2) may be PMOS transistors and/or the transistors other than the first load transistor (TL1) and/or the second load transistor (TL2) may be NMOS transistors. Thus, so as to form NMOS transistors and/or PMOS transistors, the second active region 105b and/or the third active region 105c may be doped with N-type dopants to become an N well or wells, and/or the first active region 105a and/or the fourth active region 105d may be doped with P-type dopants to become a P well or wells.

Spacers 140 may be disposed on sidewalls of the gate electrodes 130a-d. The first gate electrode 130a, which may be the gate electrode of the second drive transistor (TD2) and/or the second load transistor (TL2), may be electrically connected to the drain region of the first drive transistor (TD1), the drain region of the first load transistor (TL1), and/or the source region of the first transmission transistor (TA1). For that electrical connection, the first gate electrode 130a of the second load transistor (TL2) may be connected to the drain region of the first load transistor (TL1) through the common contact plug 180. Since the first transmission transistor (TA1) and the first drive transistor (TD1) may be disposed in the fourth active region 105d, the source region of the first transmission transistor (TA1) and the drain region of the first drive transistor (TD1) may be shared. Thus, an interconnection (not shown) may be formed so that the source region of the first transmission transistor (TA1) and/or the drain region of the first drive transistor (TD1) may be electrically connected to the common contact plug 180. That is, a contact plug 185 may be formed on the source region of the first transmission transistor (TA1) and/or the drain region of the first drive transistor (TD1), and/or a metal interconnection (not shown) may be formed so as to electrically connect the common contact plug 180 and the contact plug 185 to each other.

Also, the fourth gate electrode 130d of the first drive transistor (TD1) and/or the first load transistor (TL1) may be electrically connected to the drain region of the second drive transistor (TD2), the drain region of the second load transistor (TL2), and/or the source region of the second transmission transistor (TA2). For that electrical connection, the fourth gate electrode 130d of the first load transistor (TL1) may be connected to the drain region of the second load transistor (TL2) through the common contact plug 180. Since the second transmission transistor (TA2) and the second drive transistor (TD2) may be disposed in the first active region 105a, the source region of the second transmission transistor (TA2) and the drain region of the second drive transistor (TD2) may be shared. Thus, an interconnection (not shown) may be formed so that the source region of the second transmission transistor (TA2) and/or the drain region of the second drive transistor (TD2) may be electrically connected to the common contact plug 180. That is, the contact plug 185 may be formed on the source region of the second transmission transistor (TA2) and/or the drain region of the second drive transistor (TD2), and/or a metal interconnection (not shown) may be formed so as to electrically connect the common contact plug 180 and the contact plug 185 to each other.

The common contact plugs 180 may be conductive portions electrically connecting the first gate electrode 130a and the third active region 105c, and/or electrically connecting the fourth gate electrode 130d and the second active region 105b.

The common contact plug 180 may include a first portion 180a disposed on the first gate electrode 130a, a second portion 180b disposed on the third active region 105c, and/or a third portion 180c connecting the first portion 180a and the second portion 180b. The first, second, and/or third portions 180a, 180b, and/or 180c may be arranged along the first direction. An interlayer insulating layer 150 may remain under the third portion 180c.

A width (c) of the third portion 180c may be greater than a width (d) of the spacer 140.

The semiconductor device according to example embodiments may include a gate insulating layer 120 formed on the semiconductor substrate 100, the gate electrode 130a formed on the semiconductor substrate 100, the spacer 140 formed on a sidewall of the gate electrode 130a, the interlayer insulating layer 150 formed on an exposed surface of the semiconductor substrate 100 (e.g., the entire exposed surface), the first portion 180a disposed on the gate electrode 130a, the second portion 180b disposed on the semiconductor substrate 100, and/or the common contact plug 180, including the third portion 180c, connecting the first portion 180a and the second portion 180b. The first, second, and/or third portions 180a, 180b, and/or 180c may be arranged along the first direction. The common contact plug 180 may have a bar shape when viewed from a top plan view. The common contact plug 180 may have various shapes.

The semiconductor substrate 100 may include a silicon substrate, a germanium substrate, and/or a silicon on insulator (SOI) substrate. The device isolation layer 110 may include a silicon oxide layer, a silicon oxynitride layer, and/or a silicon nitride layer. First, second, third, and fourth active regions 105a, 105b, 105c, and 105d may be defined, at least in part, by the device isolation layer 110. The gate insulating layer 120 may include a silicon oxide layer and/or a silicon oxynitride layer. The gate electrode 130 may be conductive material and/or may include metal, metal alloy, and/or doped polysilicon. The spacer 140 formed on a sidewall of the gate electrode 130 may include a silicon nitride layer and/or a silicon oxide layer.

The interlayer insulating layer 150 formed on an exposed surface of the semiconductor substrate 100 may be, for example, a silicon oxide layer. A top surface of the interlayer insulating layer 150 may maintain a specific height by planarizing the interlayer insulating layer 150.

The interlayer insulating layer 150 may remain under the third portion 180c of the common contact plug 180. The remaining interlayer insulating layer 150 may have various shapes. The remaining interlayer insulating layer 150 may prevent damage of the spacer 140. The first portion 180a and/or the second portion 180b of the common contact plug 180 may be electrically connected to each other through the third portion 180c. A top surface of the common contact plug 180 may be planarized.

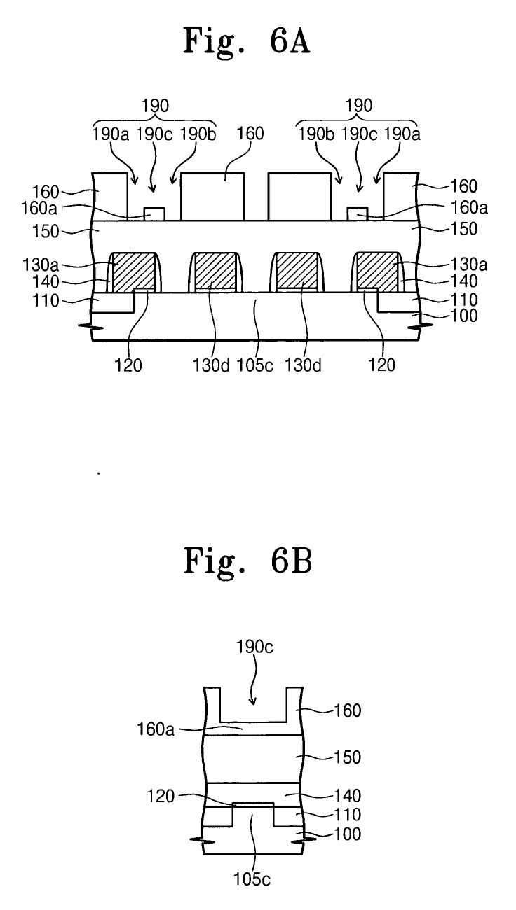

FIGS. 6A and 6B are cross-section views taken along the lines V-V′ and VI-VI′ of FIG. 5A to illustrate methods of forming semiconductor devices in accordance with example embodiments.

Referring to FIG. 6A, forming a plurality of device isolation layers 110 and/or first, second, third, and/or fourth active regions 105a, 105b, 105c, and 105d in the semiconductor substrate 100 may be included. The first, second, third, and/or fourth active regions 105a, 105b, 105c, and/or 105d may be, as described in FIG. 5A, disposed in parallel to the X axis.

A gate insulating layer 120 may be formed on the semiconductor substrate 100 in which the first, second, third, and/or fourth active regions 105a, 105b, 105c, and/or 105d may be formed. The gate insulating layer 120 may be a silicon oxide layer and/or may be formed using a thermal oxidation process.

A gate conductive layer may be formed on the semiconductor substrate 100 on which the gate insulating layer 120 may be formed. The gate conductive layer may be, for example, doped polysilicon. The gate conductive layer may be patterned to form gate electrodes 130a, 130b, 130c, and/or 130d. A spacer layer (not shown) may be formed on the semiconductor substrate 100 on which the gate electrodes 130a, 130b, 130c, and/or 130d may be formed, and then the spacer layer may be anisotropically etched to form a spacer 140. An interlayer insulating layer 150 may be formed on the semiconductor substrate 100 on which the spacer 140 may be formed. Subsequently, the interlayer insulating layer 150 may be planarized by performing a planarization process.

A common contact mask pattern 160 may be formed by spreading a photoresist and/or using the reticle 200 described in FIGS. 1A-1C and/or 2A-2C. The common contact mask pattern 160 may be formed by removing an entire portion and/or a portion of the photoresist. In the common contact mask pattern 160, a portion where an entire portion of the photoresist is removed may form a first portion 190a and a second portion 190b. A portion where a portion of the photoresist is removed may form a third portion 190c. A portion 160a of the photoresist may remain at the third portion 190c. A thickness of the photoresist portion 160a of the third portion 190c may be smaller than thicknesses of the photoresists of other portions. In the common contact mask pattern 160, the third portion 190c, which is a center of a portion 190 where a portion of the photoresist is removed, may be disposed on the spacer 140. The third portion 190c may be formed using the second phase pattern as described in FIGS. 1A-1C and 2A-2C.

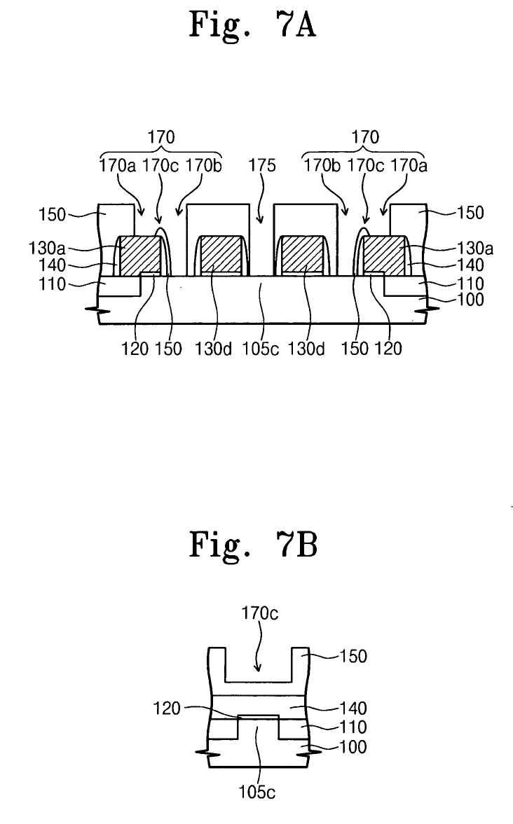

FIGS. 7A and 7B are cross-section views taken along the lines V-V′ and VI-VI′ of FIG. 5A to illustrate methods of forming semiconductor devices in accordance with example embodiments.

The interlayer insulating layer 150 may be patterned using the common contact mask pattern 160 to form a common contact hole 170 including a first portion 170a that may expose the gate electrode 130a, a second portion 170b that may expose the semiconductor substrate 100, and/or a third portion 170c that may connect the first and second portions 170a and 170b. The first, second, and/or third portions 170a, 170b, and/or 170c of the common contact hole 170 may be arranged along the first direction.

More specifically, the common contact hole 170 may be formed by the common contact mask pattern 160. The interlayer insulating layer 150 may be etched using the common contact mask pattern 160 as an etching mask to form the contact hole 170. If the interlayer insulating layer 150 is etched using the common contact mask pattern 160 as an etching mask, the first, second, and/or third portions 190a, 190b, and/or 190c of the common contact mask pattern 160 may correspond to the first, second, and/or third portions 170a, 170b, and/or 170c of the common contact hole 170, respectively. The common contact mask pattern 160 may have a different thickness of the photoresist depending on a region. If the interlayer insulating layer 150 is etched using the common contact mask pattern 160 as an etching mask, a degree of a recess of the interlayer insulating layer 150 may be different depending on a region. The interlayer insulating layer 150 may remain on the third region 170c. Conventional contact holes 175 that may expose the semiconductor substrate 100 and/or the gate electrode 130a during the etching process may be formed at the same time. The spacer 140 may have an etching selectivity with respect to the interlayer insulating layer 150 during the etching process. That is, an etching rate of the spacer 140 may be smaller than an etching rate of the interlayer insulating layer 150.

Referring to FIGS. 5A through 5C, the common contact hole 170 may be filled with a conductive material. The conductive material may include one or more of doped polysilicon, metal, and/or metal alloy. The semiconductor substrate 100 where conductive material filling the common contact hole 170 is formed may be planarized to form the common contact plug 180 and/or the contact plug 185. The conventional contact hole 175 may be filled with conductive material to form the contact plug 185. The planarization process may be performed, for example, using a chemical mechanical polishing (CMP) process and/or an etch back process. The planarization process may be performed down to the top surface of the interlayer insulating layer 150. An interconnection process connecting the common contact plug 180 and/or the contact plug 185 may be performed.

A common contact plug may be formed using a reticle including a second phase pattern according to example embodiments. Damage of a spacer disposed on a side surface of a gate electrode during a formation of the common contact hole may be reduced. Consequently, prevention of a damage of the spacer may improve reliability of a device.

While example embodiments have been particularly shown and described, it will be understood by those of ordinary skill in the art that various changes in form and details may be made therein without departing from the spirit and scope of the present invention as defined by the following claims.

What is claimed is:

1. A method of forming a semiconductor device, comprising:
forming a gate insulating layer and a gate electrode on a semiconductor substrate;
forming a spacer on a sidewall of the gate electrode;
forming an interlayer insulating layer over an exposed surface of the semiconductor substrate; and
forming a common contact hole, including a first portion exposing the gate electrode, a second portion exposing the semiconductor substrate, and a third portion connecting the first and second portions, by patterning the interlayer insulating layer;
wherein the common contact hole is formed by etching the interlayer insulating layer using a common contact mask pattern as an etch mask,
wherein the common contact mask pattern is formed by using a reticle, the reticle including:
a transparent substrate;
a first phase pattern of a first thickness disposed on the transparent substrate;
a chrome pattern disposed on the first phase pattern; and
a second phase pattern of a second thickness disposed on the transparent substrate; and
wherein the third portion is formed to correspond to the second phase pattern.

2. The method of claim 1, wherein a portion of the first phase pattern is disposed to overlap with the chrome pattern.

3. The method of claim 1, wherein the first thickness is thicker than the second thickness.

4. The method of claim 1, wherein the third portion is disposed to overlap with the spacer, and wherein the interlayer insulating layer remains on the third portion.

5. The method of claim 1, wherein the first phase pattern surrounds the second phase pattern.

6. The method of claim 1, wherein the first phase pattern contacts the second phase pattern.

7. The method of claim 1, wherein the first phase pattern comprises at least one of molybdenum and silicon.

8. The method of claim 1, wherein the first phase pattern comprises one or more of Mo, Si, O, and N.

9. The method of claim 1, wherein the second phase pattern comprises at least one of molybdenum and silicon.

10. The method of claim 1, wherein the second phase pattern comprises one or more of Mo, Si, O, and N.

11. The method of claim 1, wherein the first thickness is greater than or equal to about 80 nm and less than or equal to about 100 nm.

12. The method of claim 1, wherein the second thickness is greater than or equal to about 10 nm and less than or equal to about 100 nm.

13. The method of claim 1, wherein transmittance of the first phase pattern is greater than or equal to about 10 percent and less than or equal to about 25 percent.

14. The method of claim 1, wherein transmittance of the second phase pattern is greater than or equal to about 10 percent and less than or equal to about 25 percent.

15. The method of claim 1, wherein a width of the third portion is greater than a width of the spacer.
